(19) United States
(12) Patent Application Publication
(10) Pub. No.: US 2020/0120795 A1
(43) Pub. Date: Apr. 16, 2020

(54) METHOD FOR MANUFACTURING PRINTED CIRCUIT BOARD, PRINTED CIRCUIT BOARD AND DRIVE CIRCUIT BOARD

(71) Applicant: Wenqin Zhao, Chongqing (CN)

(72) Inventor: Wenqin Zhao, Chongqing (CN)

(21) Appl. No.: 16/311,566

(22) PCT Filed: Oct. 16, 2018
(86) PCT No.: PCT/CN2018/110496

§ 371 Date: Dec. 19, 2018

(51) Int. Cl. H05K 1/11; H05K 1/02; H05K 3/24; G09G 3/22

(52) U.S. Cl. CPC H05K 1/111; G09G 3/22; H05K 3/24; H05K 1/0287

(57) ABSTRACT

The present application pertains to the technical field of electronic circuits, and provides a method for manufacturing a printed circuit board, herein a side of each of the pads within the printed circuit board extends outward to form a protrusion, and an electrical isolation region between the protrusions of adjacent two pads is covered with tin paste.

### CROSS-REFERENCE TO RELATED APPLICATIONS

This application is the International Application No. PCT/CN2018/110496 for entry into US national phase with an international filing date of Oct. 16, 2018, designating US, now pending, and claims priority to Chinese Patent Application No. 201810979524.8, filed on Aug. 27, 2018, the content of which is incorporated herein by reference in its entirety.

### BACKGROUND OF THE INVENTION

### Field of the Invention

The present application pertains to the technical field of electronic circuits, and particularly to a manufacturing method for a printed circuit board, a printed circuit board and a drive circuit board.

### Description of Related Art

In a conventional electronic device, a printed circuit board is a core component of the electronic device. Since the printed circuit board is provided with various power supply circuits, various functional functions can be realized through the functional circuits, thus the printed circuit board is responsible for the various functions such as signal processing, signal transmission, and integrated control of information and the like in the electronic device. Therefore, the manufacturing process of the printed circuit board has an important influence on the overall manufacturing cost of the electronic device and the circuit functions to be realized, if the manufacturing process of the printed circuit board is too complicated, the manufacturing cost of electronic device will increase accordingly.

In conventional technologies, there are many discrete circuits on the printed circuit board, and each circuit module integrates a plurality of electronic components to realize corresponding circuit functions. When the printed circuit board is connected to the power supply and is in the process of normal operation, these discrete circuits need to be electrically connected to perform more complicated operations and implement corresponding circuit functions. In a conventional method for manufacturing the printed circuit board, due to the long distance between adjacent circuits, in order to achieve electrical connection between different circuits, a 0Ω resistor must be used to establish the electrical connection between two adjacent circuits, so as to enable the printed circuit board to perform normal circuit functions. Thus, the conventional method for manufacturing the printed circuit board not only has extremely high industrial manufacturing cost, but also the manufacturing process is extremely cumbersome, which leads to greatly reduced application universality of the corresponding electronic device.

### BRIEF SUMMARY OF THE INVENTION

The present application provides a manufacturing method for a printed circuit board, a printed circuit board and a drive circuit board, which aims at solving the problem, in the conventional technologies, that the method for manufacturing the printed circuit board has to use a 0Ω resistor to establish the electrical connection, thus leading to relatively high manufacturing cost for the printed circuit board, much cumbersome manufacturing process, and no application universality of related electronic device.

An embodiment of the present application provides a method for manufacturing a printed circuit board, the printed circuit board includes a plurality of electrically isolated pads, and each of the pads includes a pad body and a protrusion extending from a side of the pad body, wherein the protrusions of adjacent two of the pads are arranged oppositely, the method for manufacturing the printed circuit board includes:

arranging an electrical isolation region between the protrusions of the adjacent two of the pads;

overlapping a steel screen on the surface of the printed circuit board, wherein the steel screen is provided with meshes, and the meshes correspond to at least part of two of the pads and the electrical isolation region between the two of the pads, respectively; and

printing tin onto the surface of the steel screen, such that the electrical isolation region between adjacent two of the pads is covered with tin paste.

In one of the embodiments, the meshes correspond to two of the pads and the electrical isolation region between the two of the pads, respectively.

In one of the embodiments, printing tin onto the surface of the steel screen, such that two of the pads and the electrical isolation region between adjacent two of the pads are covered with tin paste.

In one of the embodiments, the meshes completely overlap the electrical isolation region between the two of the pads, respectively.

In one of the embodiments, the pad body is of a rectangular shape or an elliptical shape.

In one of the embodiments, printing tin onto the surface of the steel screen, such that when the electrical isolation region between adjacent two of the pads is covered with the tin paste, the method for manufacturing the printed circuit board further includes:

performing serial communication detection for adjacent two of the pads to determine whether adjacent two of the pads implement communication interconnection.

In one of the embodiments, the method for manufacturing the printed circuit board further includes:

sending communication interconnection indication signal when adjacent two of the pads can implement communication interconnection.

In one of the embodiments, that printing tin onto the surface of the steel screen, such that the electrical isolation region between adjacent two of the pads is covered with tin paste is specifically as follows:

printing tin onto the surface of the steel screen, the tin paste passes through the meshes of the steel screen and flows onto the electrical isolation region between adjacent two of the pads, and the tin paste fails to flow through the region of the steel screen without meshes, such that the electrical isolation region between adjacent two of the pads is covered with the tin paste.

An embodiment of the present application provides a printed circuit board, which includes a plurality of electrically isolated pads, each of the pads includes a pad body and a protrusion extending from a side of the pad body, the protrusions of adjacent two of the pads are arranged oppositely, and the region between the protrusions of adjacent two of the pads is covered with tin paste.

In one of the embodiments, in the pads, the pad body is of a rectangular shape or an elliptical shape.

In one of the embodiments, the printed circuit board further includes:

a communication detector, and the communication detector is connected to the pads, the communication detector detects whether adjacent two of the pads can implement communication interconnection.

In one of the embodiments, the printed circuit board further includes:

a status display, the status display is connected to the communication detector, and the status display is configured to display communication interconnection information of the adjacent two of the pads.

In one of the embodiments, the adjacent two of the pads and the region between the protrusions of the adjacent two of the pads are covered with the tin paste.

An embodiment of the present application provides a drive circuit board, which includes a first pad and a second pad, wherein the first pad comprises a first pad body and a first protrusion extending from a side of the first pad body, the second pad comprises a second pad body and a second protrusion extending from a side of the second pad body, wherein the first protrusion and the second protrusion are arranged oppositely;

and the region between the first protrusion and the second protrusion is covered with tin paste.

In one of the embodiments, the first pad body is of a rectangular shape or an elliptical shape, and the second pad body is of a rectangular shape or an elliptical shape.

In one of the embodiments, the first pad and the second pad implement communication connection through the tin paste.

In one of the embodiments, the first pad, the second pad and the region between the first protrusion and the second protrusion are covered with the tin paste.

In one of the embodiments, the first pad includes:

a power circuit, configured to output DC power; and

a control circuit, connected to the power circuit, and configured to access a display drive signal and generate a display control signal;

the second pad comprises:

a gate drive circuit, configured to receive the display drive signal according to the display control signal; and

a source drive circuit, configured to convert and then output the display drive signal according to the display control signal.

In one of the embodiments, the power circuit comprises a power management chip, and the control circuit comprises a display drive chip.

In one of the embodiments, the drive circuit board further includes:

a display-panel-status display, the display-panel-status display is connected to the first pad and the second pad, and the display-panel-status display displays communication interconnection information on the first pad and the second pad.

In the above method for manufacturing the printed circuit board, each of the pad on the printed circuit board includes a pad body and a protrusion extending from a side of the pad body, and adjacent two of the pads are correspondingly arranged by the protrusion, and there is a short spatial distance between the protrusions of different pads, therefore the different pads are closer to each other through the protrusion. Through providing an electrical isolation region between the protrusions of adjacent two of the pads, overlapping a steel screen on the surface of the printed circuit board, and meshes are provided on the steel screen, and the meshes respectively corresponds to at least part of two pads and the electrical isolation region between the two pads. Since tin paste has fluidity, the solder paste will pass through the meshes of the steel screen and flows onto the electrical isolation region on the printed circuit board, and the protrusions of the different pads are electrically connected by the tin paste. Meanwhile, the tin paste cannot pass through the region without meshes in the steel screen, thus ensuring physical safety of the pads within the printed circuit board. Therefore, the method for manufacturing the printed circuit board in the present application can achieve electrical connection between the two pads by adding the tin paste between the protrusions of the pads, there is no requirement for an additional 0Ω resistor, and the manufacturing cost is low. Moreover, no special punching operation is required on the printed circuit board, which simplifies the manufacturing steps of the printed circuit board and is easy to implement, and greatly improves application range of the method for manufacturing the printed circuit board, and has high practicability. Therefore, the present application effectively solves the problems, in the exemplary technology, that the method for manufacturing the printed circuit board must use a 0Ω resistor to implement electrical connection, thus resulting in high manufacturing cost of the printed circuit board, complicated manufacturing process, and difficulty in universal application.

### BRIEF DESCRIPTION OF THE DRAWINGS

In order to more clearly illustrate the technical solutions in the embodiments of the present application, the drawings used in the description of the embodiments will be briefly described below. Obviously, the drawings in the following description are only some embodiments of the present application, and other drawings can also be obtained based on these drawings for those skilled in the art without paying any creative effort.

FIG. 1 is a structural schematic view of a printed circuit board provided in an embodiment of the present application.

FIG. 2 is a flow chart of realizing a method for manufacturing the printed circuit board provided in an embodiment of the present application.

FIG. 3 is a flow chart of realizing another method for manufacturing the printed circuit board provided in an embodiment of the present application.

FIG. 4 is a schematic view of modules of another printed circuit board provided in an embodiment of the present application.

FIG. 5 is a schematic view of modules of a drive circuit board provided in an embodiment of the present application.

FIG. 6 is a schematic view of modules of a display device provided in an embodiment of the present application.

FIG. 7 is a schematic view of modules of a display system provided in an embodiment of the present application.

### DESCRIPTION OF THE EMBODIMENTS

In order to make the purpose, technical solutions and advantages of the present application more clear, the present application will be further described in detail below with reference to the drawings and embodiments. It should be understood that, the specific embodiments described herein are merely for explaining the present application, and not intended to limit the present application.

It should be noted that, in the printed circuit board, the connection method between different pads is a key factor affecting the manufacturing cost of the printed circuit board and the circuit functions of the printed circuit board. Moreover, with the rapid development of the manufacturing process of the printed circuit board, in an exemplary technology, the conventional printed circuit board uses a 0Ω resistor to establish electrical connection between adjacent pads, given the relatively long distance between the adjacent pads. Herein, The 0Ω resistor acts as a jumper resistor, and is a resistor for special applications in the printed circuit board. Since the resistance of the 0Ω resistor is very low, almost close to 0, the electrical connection between micro devices can be realized through the 0Ω resistor, and the power signal has high accuracy and low signal loss during transmission at the 0Ω resistor. However, the 0Ω resistor needs to be made of a material with extremely low resistivity and excellent electrical conductivity, and the manufacturing environment and process flow of the 0Ω resistor are extremely complicated, thus the production cost of the 0Ω resistor itself is high. If a large number of 0Ω resistors are used in the printed circuit board, the manufacturing cost of the printed circuit board will increased largely, thereby reducing the practical performance of the printed circuit board. Additionally, when the 0Ω resistor is applied to the printed circuit board, the punching operation must be performed for the printed circuit board such that the 0Ω resistor can be completely soldered in the printed circuit board, so as to realize electrical connection between different pads, which will greatly increase the manufacturing steps of the printed circuit board, and will cause the manufacturing process of the printed circuit board more cumbersome, and the difficulty of manufacturing the printed circuit board is increased in technology.

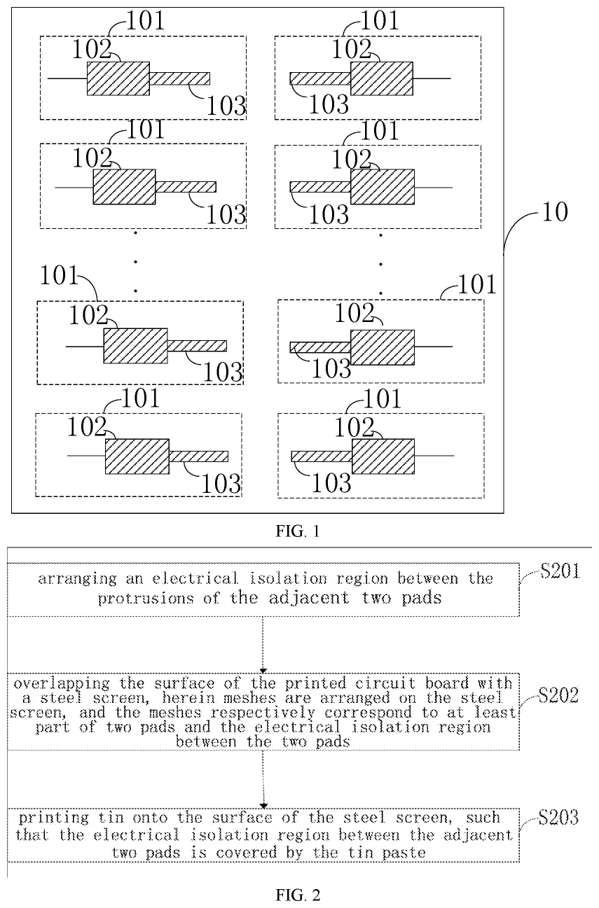

Therefore, in the exemplary technology, the method for manufacturing the printed circuit board is relatively high, the manufacturing process is cumbersome, and the practicability is relatively low. With regard to this problem, an embodiment of the present application provides a method for manufacturing the printed circuit board, in which there is no need to arrange a 0Ω resistor in the printed circuit board, and the electrical connection between adjacent pads can be realized merely through tin paste, thereby greatly reducing the manufacturing cost of the printed circuit board, simplifying the manufacturing process of the printed circuit board, and causing the printed circuit board in the embodiments of the present application to have a wider application range and strong practicability. Specifically, FIG. 1 shows a structure schematic of the printed circuit board 10 provided in an embodiment of the present application, as shown in FIG. 1, the printed circuit board 10 includes a plurality of electrically isolated pads 101, and there is no access to directly carry out electric energy transmission and signal transmission between different pads, at this moment each of the pads 101 is a separated circuitry to respectively perform corresponding circuit function. Herein, the pad 101 includes a pad body 102, the pad body 102 includes various electronic components such as a resistor, a capacitor etc., and the electronic components may realize corresponding circuit functions according to corresponding control signals. Herein, the pad 101 further includes a protrusion 103 extending from a side of the pad body 102, the peripheral contact area of the pad 101 may be prolonged through the protrusion 103, and adjacent two pads are arranged opposite to each other through the protrusion. Specifically, as shown in FIG. 1, the protrusions of the adjacent two pads are close to each other, and the distance between the protrusions 103 is shortest in the peripheral contact areas of the two pads. Thus each of the pads 101 is provided with the protrusion 103 extending outward, the distance between the adjacent pads is shorter, which is more advantageous for realizing the electrical connection between the adjacent two pads. In the printed circuit board 10 shown in FIG. 1, the structure of the pads is simple by arranging the protrusions 103 on the pad bodies 102, and the space between the adjacent two pads may be greatly reduced through the protrusions 103, and it is easier to perform transmission and interaction of signals between different pad bodies, thereby improving the connection convenience between different pads in the printed circuit board 10.

Herein, FIG. 2 shows a flow chart of realizing the method for manufacturing the printed circuit board 10 provided in an embodiment of the present application. As shown in FIG. 2, the method for manufacturing the printed circuit board 10 specifically includes:

Step S201: arranging an electrical isolation region between the protrusions of the adjacent two pads. Specifically, in conjunction with the structure schematic of the printed circuit board in FIG. 1, there exists the electrical isolation region between the protrusions of the adjacent two pads, thus the two adjacent pads have no access to direct communication interconnection with each other, herein the electrical isolation region may accommodate conductor material such as tin, aluminum, etc. Since the distance between adjacent two protrusions is shortest on the edges of the two pads, so there is the electrical isolation region with small area between the protrusions of the adjacent two pads on the printed circuit board 10, so that the protrusions of the adjacent two pads are electrically connected through the conductor material in the electrical isolation region, and the communication interconnection between the adjacent two pads are more convenient.

Step S202: overlapping the surface of the printed circuit board 10 with a steel screen, herein meshes are arranged on the steel screen, and the meshes respectively correspond to at least part of two pads and the electrical isolation region between the two pads. Due to that the steel screen is made of wire mesh and the steel screen has the characteristics of corrosion resistance and high temperature resistance, the conductive material can be accurately transferred onto the circuit board through the steel screen in the manufacturing process of the printed circuit board. At step S202, the tin paste may flow to partial region of the pad and the electrical isolation region through the meshes of the steel screen, and instead, the tin paste cannot pass through the region of the steel screen without meshes, therefore, the tin paste may be accurately etched on a predetermined region of the printed circuit board 10 through the meshes of the steel screen in the embodiment of the present application, thereby improving the etching precision of the printed circuit board 10.

Step S203: printing tin onto the surface of the steel screen, such that the electrical isolation region between the adjacent two pads is covered by the tin paste. As described above, since the electrical isolation region is arranged between the protrusions of the adjacent two pads, the tin paste will deposits on the underlying printed circuit board 10 through the meshes of the steel screen during the process of uniformly printing tin onto the surface of the steel screen. Further, since the steel screen is divided into two parts: a region with meshes and a region without meshes, during the process of printing tin on the steel screen, the tin paste may only pass through the region with meshes of the steel screen, and the tin paste will not pass through the region without meshes. Therefore, through printing tin onto the surface of the steel screen, and then the tin paste passes through the meshes of the steel screen and flows onto the electrical isolation region of the printed circuit board 10 and the partial region of the two pads. Due to that the tin paste has excellent electrical conductivity, after the electrical isolation region of the printed circuit board 10 is completely covered by the tin paste, the protrusions of the adjacent two pads are electrically connected by the tin paste, thus the adjacent two pads are capable of power transmission and signal transmission, and the various pads within the printed circuit board 10 may interconnected with each other to form a power system, so as to achieve more complex circuit functions. Moreover, the meshes of the steel screen respectively corresponds to the at least part of the two pads and the electrical isolation region on the printed circuit board 10, therefore, through arranging the electrical isolation region at a specific position of the printed circuit board 10, different power transmission lines may exist in the printed circuit board 10, and each of the power transmission lines is electrically connected by the tin paste, thereby avoiding the presence of falsely triggering power in the printed circuit board 10, and protecting the physical security of the pads within the printed circuit board 10.

Therefore, in the above-described method for manufacturing the printed circuit board 10, since the electrical isolation region is arranged between the protrusions of the adjacent two pads, and the meshes of the steel screen respectively corresponds to the at least part of the two pads and the electrical isolation region between two pads, the electrical isolation region may be completely covered by the tin paste. According to the internal constituent material of the pads, the middle line of the pad is made of bare copper, and the tin paste in the electrical isolation region may be tightly adhered on the pads, which is not easy to fall off, thus ensuring that the protrusions of the pads may be well connected with each other, such that there is good electrical connection between the adjacent two pads, and the security and stability of the electrical connection between different pads within the printed circuit board 10 are improved.

In the embodiments of the present application, the isolation region is arranged between the protrusions of the adjacent two pads, and the surface of the steel screen is printed with the tin, and then the tin paste flows onto the electrical isolation region of the printed circuit board 10 and the adjacent two pads through the meshes of the steel screen. A large amount of tin paste is deposited on the electrical isolation region, and the protrusions of the adjacent two pads are electrically connected by the tin paste, such that the pads within the printed circuit board 10 are electrically connected through the electrical isolation region. Different pads may perform communication interconnection with each other to achieve more complicated circuit functions. Therefore, in the method for manufacturing the printed circuit board 10 in the embodiments of the present application, the electrical connection between the adjacent two pads may be realized by the tin paste on the electrical isolation region with the printed circuit board 10, and no 0Ω resistor is required, which saves the device cost during the manufacturing process of the printed circuit board, and avoids the device loss caused during the manufacturing process of the printed circuit board. Additionally, there is no requirement of punching operation for the 0Ω resistor in the method for manufacturing the printed circuit board 10 in the embodiments of the present application, which simplifies the manufacturing process of the printed circuit board 10, and the adjacent two pads are electrically connected by the tin paste deposited in the electrical isolation region within the printed circuit board 10, which is easy to operate and easy to implement. Therefore, the method for manufacturing the printed circuit board 10 in the embodiments of the present application has extremely simplified operation steps and relatively low manufacturing cost, and when the printed circuit board 10 is applied in an electronic device, the printed circuit board 10 may efficiently facilitate the electronic device to implement the corresponding circuit functions, and improve the practicability of the corresponding electronic device, thus solving the problem that the manufacturing cost of the printed circuit board in the exemplary technology is relatively high and the manufacturing steps are too complicated, thereby leading to no application universality of corresponding electronic device.

As an alternative implementation, after the step S203, the method for manufacturing the printed circuit board 10 in the embodiment further includes:

performing serial communication detection for the adjacent two pads to determine whether the adjacent two pads implement communication interconnection with each other.

In the present embodiment, after the electrical isolation region between the adjacent two pads is covered by the tin paste, the tin paste serves as a transmission medium for data communication, and can realize signal transmission between different pads. In order to ensure the safe and stable data communication between different pads within the printed circuit board 10, serial communication detection for the adjacent two pads are performed, so as to prevent the problem, which results in a high failure rate of the printed circuit board, that the adjacent two pads still have no access to normal data communication after the surface of the steel screen is printed with the tin. Therefore, through performing serial communication detection for the adjacent two pads in the present embodiment, it is determined whether the communication interconnection between the adjacent two pads is realized, thus improving the efficiency and practical value of the method for manufacturing the printed circuit board in the embodiment, ensuring that normal serial communication may always be performed between different pads within the printed circuit board 10, and reducing the communication failure rate of the printed circuit 10. This method for manufacturing the printed circuit board 10 greatly improves the communication stability between different electronic components, and has a wider range of adaptation.

As an alternative implementation, the above method for manufacturing the printed circuit board 10 further includes: sending an interconnection indication signal when the adjacent two pads have access to communication interconnection.

As described above, after the electrical isolation region between the adjacent two pads is covered by the tin paste, if the adjacent two pads realize communication interconnection, then the electronic components on the two pads constitute a whole circuit system and different pads on the printed circuit board may cooperate with each other to realize more complicated circuit functions. After the adjacent two pads are successfully interconnected with each other, then the interconnection indication signal is sent to a technician in time, and the interconnection indication signal can intuitively transmit the information about the successful interconnection to the technician. Therefore, the technician can master the interconnection state between different pads in real time according to the interconnection indication signal, which improves operability of the pads within the printed circuit in the embodiment, and the user can accurately obtain the working state of the electronic components in the printed circuit board 10. The method for manufacturing the printed circuit board 10, in the embodiment, has higher human-computer interaction performance, and ensures the security and stability of communication the interconnection between the adjacent two pads.

As an alternative implementation, at step S202, the meshes respectively correspond to the two pads and the electrical isolation region between the two pads, thereby making the meshes of the steel screen respectively completely overlap the two pads and the electrical isolation region between the two pads. During the process of printing tin onto the surface of the steel screen, the tin paste completely covers the two pads and the electrical isolation region between the two pads through the meshes of the steel screen, so as to achieve the electrical connection between the adjacent two pads, and correspondingly, the printed circuit board 10 can implement more complicated circuit functions.

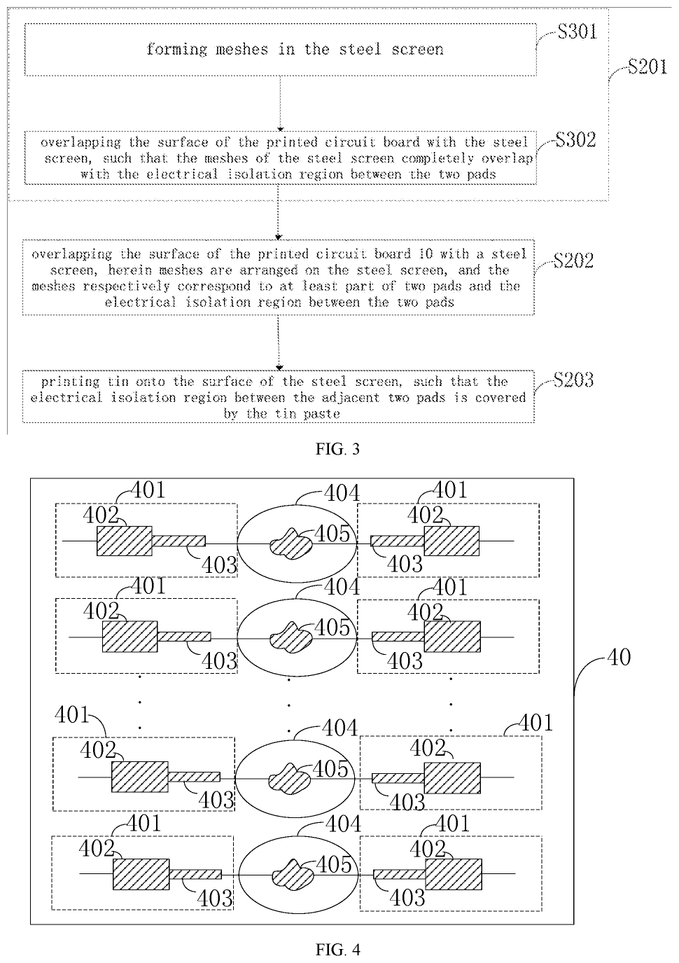

As a preferred implementation, FIG. 3, compared with the method for manufacturing the printed circuit board 10 as shown in FIG. 2, shows another flow chart of realizing the method for manufacturing the printed circuit board 10 provided in an embodiment of the present application. As shown in FIG. 3, the step S201 specifically includes:

Step S301: forming meshes in the steel screen. Through punching to the steel screen, when a fluid substance exists on the surface of the steel screen, the fluid substance penetrates through the meshes of the steel screen, and then during the process of printing tin onto the surface of the steel screen, the tin paste is transferred to the surface of the printed circuit board 10 through the meshes of the steel screen, so that the soldering process of the printed circuit board 10 can be safely performed, and the safety of the manufacturing process of the printed circuit board 10 is ensured.

Step S302: overlapping the surface of the printed circuit board 10 with the steel screen, such that the meshes of the steel screen completely overlap with the electrical isolation region between the two pads, respectively. Since only the region with meshes in the steel screen can pass through the tin paste, and the region without meshes in the steel screen cannot pass through the tin paste, thus at step S302, the meshes of the steel screen completely overlap with the electrical isolation region on the printed circuit board 10 respectively, such that the tin paste on the steel screen may be transferred to the electrical isolation region on the printed circuit board, thereby it ensures that the tin paste may only flow onto the electrical isolation region on the printed circuit board 10, and any tin paste cannot flow through the region without meshes in the steel screen. Therefore, the soldering accuracy of the printed circuit board is improved, and the problem, that the tin paste is wasted during the method for manufacturing the printed circuit board 10, is solved. Moreover, the protrusions of the adjacent two pads can realize accurate electrical connection through the tin paste in the electrical isolation region, such that the printed circuit board 10 can realize stable and complicated circuit functions.

As an alternative implementation, the above printed circuit board 10 includes two or three electrically isolated pads 101. The method for manufacturing the printed circuit board in the embodiments of the present application can be applied to different types of pads with different circuit functions, the application range of which is extremely wide, and the technician can preset the number of the pads within the printed circuit board 10 according to the circuit function required by the corresponding electronic device, thus the method for manufacturing the printed circuit board is extremely compatible, such that the circuit functions realized by the printed circuit board 10 can effectively meet the actual needs of the technicians and improve the practicability of the corresponding electronic device.

As an alternative implementation, in the above printed circuit board 10, the pad bodies 102 are of a rectangular shape or an elliptical shape, and the technician may preset the shape of the pad bodies 102 within the printed circuit board 10, so as to satisfy the requirements of the circuit functions realized by each of the pads. The method for manufacturing the printed circuit board in the embodiments enables the pad bodies 102 with different shapes to be electrically connected through the tin paste, and the different pad bodies 102 may cooperate with each other to realize more complicated circuit functions, which is extremely compatible. The method for manufacturing the printed circuit board in the embodiment can be applied to printed circuit boards having different circuit functions, and can be widely applied to different industrial fields, and has higher practical value.

FIG. 4 shows a structure of circuits of the printed circuit board 40 provided by an embodiment of the present application. As shown in FIG. 4, the printed circuit board 40 includes a plurality of electrically isolated pads 401, and each of the pads 401 includes a pad body 402 and a protrusion formed by extending from one side of the pad body 402, wherein a plurality of electronic circuits are integrated on the pad body 402, so that the pads 401 may implement relatively complicated circuit functions. The protrusions of the adjacent two pads are oppositely disposed, and then the protrusions of the adjacent two pads are close to each other. Moreover, the tin paste 405 is deposited in the regions 404 between the protrusions of the adjacent two pads, such that the regions 404 between the protrusions of the adjacent two pads are covered with the tin paste, and the protrusions of the adjacent two pads are electrically connected through the tin paste 405. Referring to the above specific implementations as shown in FIG. 1 to FIG. 3, since the pad bodies 402 are added with the protrusions 403 extending outward in the embodiment of the present application, and the distance between the adjacent two pads is greatly shortened through the protrusions 403. During the manufacturing process of the printed circuit board 40, the steel screen is punched, and the tin paste flows onto the regions 404 between the protrusions of the adjacent two pads through the meshes of the steel screen, and the adjacent two pads within the printed circuit board 40 are electrically connected through the tin paste 405 in the regions 404. After different pads are electrically connected, the plurality of pads on the printed circuit board 40 may cooperate with each other to achieve more complicated circuit functions, thereby greatly simplifying the circuit structure on the printed circuit board 40, the compatibility of which is stronger. Therefore, the printed circuit board 40 in the embodiment of the present application may utilize the tin paste 405 in the regions 404 between the protrusions of the two pads, instead of the 0Ω resistor in the exemplary technology, to achieve the electrical connection between different pads, which saves manufacturing cost and industrial application cost of the printed circuit board 40. The printed circuit board 40 in the embodiment of the present application has a relatively simplified circuit structure, and may be applied to different types of electronic devices to realize corresponding circuit functions, thus having a wide range of applications, and effectively solving the problems that the printed circuit board in the exemplary technology must rely on the 0Ω resistor to realize the electrical connection between different pads, the manufacturing cost and the industrial application cost of the conventional printed circuit board are relatively high, and the circuit structure on the printed circuit board is too complicated to be applied to different types of electronic devices, thus the practicability is low.

As an alternative implementation, in the pads 401, the pad bodies 402 are in a rectangular shape.

As an alternative implementation, in the pads 401, the pad bodies 402 are in an elliptical shape, therefore the printed circuit board 40 provided by the embodiment may be compatible with the pad bodies 402 having different shapes to achieve different circuit functions. According to actual needs, the technician may preset the specific shape of the pad bodies 402, thus the flexibility of which is extremely strong. Moreover, the printed circuit board 40 in the embodiment may be applied to various industrial fields, and the application range is extremely wide, thereby greatly improving the practical value of the printed circuit board 40 in the embodiment.

As an alternative implementation, the printed circuit board 40 further includes: a communication detector connected to the pads 401, and the communication detector detects whether the adjacent two pads 401 are interconnected with each other.

In the embodiment, the printed circuit board 40 is further provided with the communication detector, which is capable of detecting the serial communication state between different pads 401. Since the regions between the protrusions of the adjacent two pads are covered by the tin paste, the communication detector in the embodiment may detect normal data communication between the two adjacent pads, so as to ensure stable, safe and continuous data communication between different pads within the printed circuit board 40. The different pads within the printed circuit board 40 may cooperate with each other to form a whole circuit, and always stay in a normal working state. The printed circuit board 40 can realize more complicated circuit functions, thus improving the application range of the printed circuit board 40.

Alternatively, the communication detector in the embodiment may be implemented by using a bidirectional communication test and measurement circuit in an exemplary technology, wherein the bidirectional communication test and measurement circuit includes electronic components such as a central processor, a resistor, and a capacitor and the like. Optionally, the model of the central processor is: S3C2440A. When the bidirectional communication test and measurement circuit is applied in the printed circuit board 40, the bidirectional communication test and measurement circuit outputs a communication test signal to the adjacent two pads, the adjacent two pads generates a feedback signal after receiving the communication test signal, and the central processor may determine whether the adjacent two pads have successfully realized communication interconnection through the feedback signal, which is easy to operate, and has extremely high accuracy for the serial communication detection between the adjacent two pads. Therefore, the communication state between different pads may be monitored in real time through the adjacent two pads in the embodiment, which greatly improves the security and stability of data communication in the printed circuit board 40.

As an alternative implementation, the above printed circuit board 40 further includes:

a status display, the status display is connected to the communication detector, and the status display displays communication interconnection information on the two adjacent pads.

In the embodiment, after the communication detector detects whether the two adjacent pads within the printed circuit board 40 are interconnected with each other, the communication detector transmits the detection result to the status display, and then the communication interconnection information on the adjacent two pads may be displayed in real time through status displaying. Through the state display, the technician may intuitively acquire whether the two pads successfully realize communication interconnection, and the experience of the technician is better. During the normal working process of the printed circuit board 40, the status display can display the communication interconnection information between different pads in real time, and avoid the phenomenon of communication interruption between the adjacent two pads within the printed circuit board 40. The different electronic components within the printed circuit board 40 may always form a circuitry, so as to perform more complicated circuit functions. Therefore, in the embodiment, the technician may monitor the interconnection state between different pads in real time through the status display, and avoid communication interruption between the adjacent two pads within the printed circuit board 40, thereby the communication quality between the adjacent two pads within the printed circuit 40 is improved, and the printed circuit board 40 in the embodiment has a higher practical value.

Alternatively, the status display may be implemented by using a video display circuit in an exemplary technology, and the video display circuit includes electronic components such as a resistor, a MOS tube, and a LED (Light Emitting Diode) and the like, wherein the communication interconnection information between the adjacent two pads is displayed by the light emitting state of the LED. Exemplarily, when the two adjacent pads within the printed circuit board 40 have successfully implemented communication interconnection with each other, the LED emits light normally; and when the adjacent two pads within the printed circuit boards 40 have not implemented communication interconnection with each other, the LED does not emit light, thus the communication state of the adjacent two pads within the printed circuit board 40 may be accurately reflected by the illumination condition of the LED. Therefore, the state display in the embodiment has a relatively simplified circuit structure, is easy to implement, and can effectively improve the human-computer interaction performance of the printed circuit board 40.

As an alternative implementation, in the above printed circuit board 40, the adjacent two pads 401 and the regions 404 between the protrusions of the adjacent two pads are covered with the tin paste 405. On the one hand, since the tin paste 405 may be tightly adsorbed on the pad 401, and the tin paste 405 is prevented from falling off from the printed circuit board 40, thus the communication safety between the adjacent two pads 401 is improved. On another hand, since the tin paste 405 has extremely strong electrical conductivity, the adjacent two pads 401 may quickly perform interconnection and power transmission through the tin paste 405, and the plurality of pads 401 may cooperate with each other to realize more complicated circuit functions, thus having relatively high practical value. Therefore, the plurality of pads 401 in the embodiment can realize communication interconnection with each other through the tin paste 405, the transmission efficiency of the communication signal is high, and the manufacturing cost of the printed circuit board 40 is low, thereby greatly improving the application range of the printed circuit board 40.

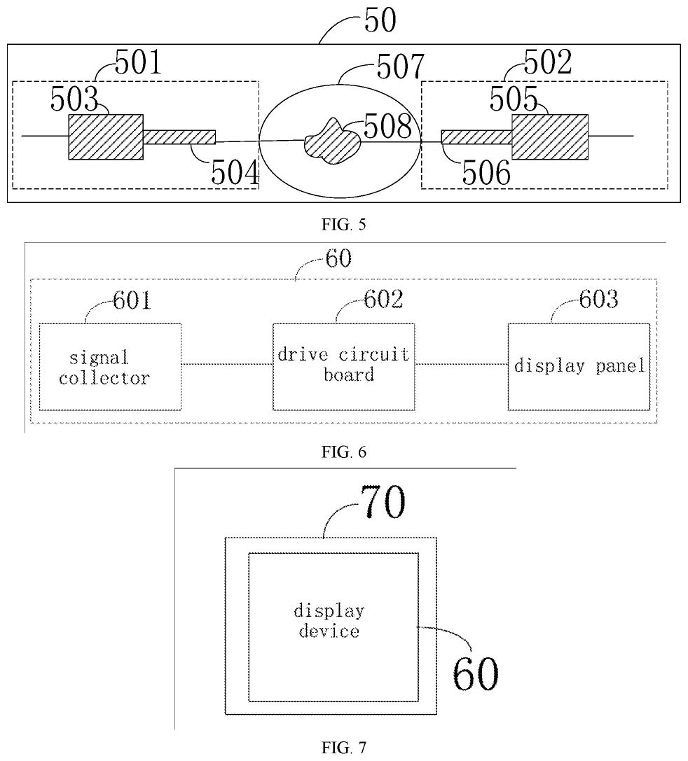

FIG. 5 shows a structure of circuits of the drive circuit board 50 provided by an embodiment of the present application. The drive circuit board 50 can transmit and process a display drive signal, and the display drive signal can drive the display to display a corresponding image or video. Specifically, as shown in FIG. 5, the drive circuit board 50 includes a first pad 501 and a second pad 502, wherein corresponding functional circuits are respectively integrated into the first pad 501 and the second pad 502, thus the first pad 501 and the second pad 502 may independently implement respective circuit functions. The first pad 501 includes a first pad body 503 and a first protrusion extending from a side of the first pad body 503, the second pad 502 includes a second pad body 505 and a second protrusion 506 extending from a side of the second pad body 505, wherein the first protrusion 504 and the second protrusion 506 are oppositely disposed, and the distance between the first protrusion 504 and the second protrusion 506 is the shortest between the edge of the first pad 501 and the edge of the second pad 502. In the embodiment of the present application, the spatial distance of the two pads (including The first pad 501 and the second pad 502) within the drive circuit board 50 has been greatly shorten through the protrusions (including the first protrusion 504 and the second protrusion 506), thus the first pad 501 and the second pad 502 are easier to implement electrical connection.

Herein, the tin paste 508 is deposited in a region 507 between the first protrusion 504 and the second protrusion 506, so that the region 507 is completely covered by the tin paste, and the first protrusion 504 and the second protrusion 506 are electrically connected by the tin paste 508, such that the first pad 501 and the second pad 502 on the drive circuit board 50 may perform communication interconnection to realize the overall circuit functions. It should be noted that, the manufacturing process and the working principle of the drive circuit board 50 in the embodiment of the present application may refer to the above embodiments of FIG. 1 to FIG. 3, and the details of which are not described herein again. In combination with the above contents, in the structure of the circuits of the drive circuit board 50 in the embodiment of the present application, the first pad 501 and the second pad 502 are electrically connected merely through the tin paste 508, and no additional auxiliary devices, such as the 0Ω resistor, are needed, thus greatly simplifying the circuit structure of the drive circuit board 50, reducing the manufacturing cost of the corresponding display, and improving the practicability of the corresponding display. Simultaneously, during the process that the drive circuit board 50 transmits the display drive signal, the first pad 501 and the second pad 502 may achieve fast signal transmission and communication interconnection through the tin paste 508, thereby enabling electronic components located on different pads (including the first pad 501 and the second pad 502) to cooperate with each other, so as to achieve more complicated circuit functions. The display drive signal may be sequentially output through the first pad 501, the tin paste 508 and the second pad 502, and the electronic components on the first pad 501 and the electronic components on the second pad 502 perform function conversion and transmission for the display drive signal. When the drive circuit board 50 is applied to the display, the display can receive a large amount of display drive signals in real time, and the display displays high-definition and dynamic images based on the display drive signals. Therefore, the drive circuit board 50 in the embodiment of the present application has an extremely simplified circuit structure, and can realize fast transmission and conversion for the display drive signals, which may be widely applied to different types of displays, and is extremely compatible.

As an alternative implementation, in the above drive circuit board 50, the first pad body 503 is in a rectangular or elliptical shape, and the second pad body 505 is in a rectangular or elliptical shape, and then the drive circuit board 50 in the embodiment has strong compatibility. The first pad 501 and the second pad 502 may include electronic components with different functions, and the drive circuit board 50 can implement more comprehensive circuit functions to meet the actual needs of the technician.

In the embodiment, the first pad 501 and the second pad 502 are communicably connected through the tin paste 508, and then the electronic components within the first pad 501 and the electronic components within the second pad 50 are communicably interconnected through the tin paste 508, so as to form a whole circuit, which effectively reduces the communication interconnection cost of the electronic components within the drive circuit board 50 of the embodiment.

As an alternative implementation, in the above drive circuit board 50, the first pad 501, the second pad 502, and the region 507 between the first protrusion 504 and the second protrusion 506 are covered by the tin paste 508, and then the tin paste 508 in the embodiment may be tightly connected to the first pad 501 and the second pad 502, thus improving the communication quality and the communication safety between the first pad 501 and the second pad 502. That is to say, the manufacturing cost of the drive circuit board 50 is reduced, and all the electronic components within the drive circuit board 50 are ensured always in a safe and stable operating state.

As a specific implementation, in the above drive circuit board 50, the first pad 501 includes a power circuit and a control circuit, wherein the power circuit outputs DC power. Specifically, the power circuit is connected to external power and converts the external power into the DC power, through which a nominal voltage may be supplied to the circuits on the first pad 501 and the circuits on the second pad 502 to ensure that the electronic components on the drive circuit board 50 may be in normal working state. The control circuit may centrally process the signals and convert the signals to output, wherein the control circuit is connected to the power circuit, and the power circuit transmits the DC power to the control circuit, so as to drive the control circuit to maintain a stable working state. Moreover, the control circuit may access the display drive signals and generate display control signals, wherein the display drive signals include a large amount of image data, and the display drive signals may drive the display to display dynamic and clear images or videos. The display control signals include user control commands and user operating information, through which the operating states of the various circuits within the pads (including the first pad 501 and the second pad 502) may be controlled. Further, in the embodiment of the present application, the first pad 501 may access the display drive signal through the control circuit, so as to implement the information exchange between the drive circuit board 50 and the external electronic devices, and the first pad 501 may be configured to control the working state of the display through the display control signal generated by the control circuit, which is easy to operate and has strong practicability.

The second pad 502 includes a gate drive circuit and a source drive circuit. As described above, since the first pad 501 and the second pad 502 are electrically connected through the tin paste 508, then the circuits within the first pad 501 (including the power circuit and the control circuit) and the circuits within the second pad 502 (including the gate drive circuit and the source drive circuit) are capable of bidirectional signal transmission. Specifically, the gate drive circuit receives the display control signal and the display drive signal, and the gate drive circuit receives the display drive signal according to the display control signal. The working state of the gate drive circuit may be controlled through the display control signal. If the gate drive circuit is turned on, the second pad 502 may receive the display drive signal, the display drive signal enables the display to be in a normally working state, and the gate drive circuit has good controllable performance. The source drive circuit receives the display control signal and the display drive signal, then the source drive circuit may be at an on-state or at an off-state by the display control signal. Further, the source drive circuit performs function conversion for the display drive signal according to the display control signal, so that the display drive signal outputted by the source drive circuit has a display drive function. Therefore, in the embodiments of the present application, with combination of converting and transmitting the display drive signal by the gate drive circuit and the source drive circuit, the display drive signal can drive the display to implement normal image or video displaying, so that the drive circuit board 50 can always be at stable working state.

In the embodiment of the present application, since the circuits (including the power circuit and the control circuit) within the first pad 501 and the circuits (including the gate drive circuit and the source drive circuit) within the second pad 502 are communicably connected through the tin paste, which not only reduces the manufacturing cost of the drive circuit board 50, but also simplifies the circuit structure within the drive circuit board 50. In addition, the circuits on different pads may cooperate with each other to convert and transmit the display drive signals, thus the display drive signals may be quickly transmitted in the drive circuit board 50, and the corresponding display may display clear images or videos according to the display drive signals, which improves the practical value of the display, and thereby The drive circuit board 50 in the embodiments of the present application may be adapted into different types of displays.

It should be noted that, the power circuit, the control circuit, the gate drive circuit and the source drive circuit may all be implemented by a specific circuit structure in an exemplary technology. For example, the power circuit may use a power management chip to achieve power convention and output functions, wherein the power management chip is of the type KA1L0380RB. For example, the control circuit may use a display drive chip, wherein the display drive chip is of the type MST717C. For example, the gate drive circuit includes a MOS tube array and a resistor, wherein the MOS tube array includes a plurality of interconnected MOS tubes, When the MOS tube array accesses the display control signal, the MOS tube may be controlled to be turned on or turned off by the level state of the display control signal. When the MOS tube array is turned on, the gate drive circuit may access the display drive signal in real time. For example, the source drive circuit includes electronic components such as a diode and a switching tube, and when the source drive circuit accesses the display control signal, the display control signal may control the working state of the source drive circuit, then function convention is performed for the display control signal through the diode and the switching tube. The display drive signal may achieve the corresponding display drive functions, therefore once the display receives the image data contained in the display drive signal, the corresponding video displaying function may be achieved.

As an alternative implementation, the printed circuit board 50 further includes:

a status display of a display panel, the status display of the display panel is connected to the first pad 501 and the second pad 502, and the status display of the display panel displays communication interconnection information on the first pad 501 and the second pad 502.

In the present embodiment, as described above, since a large amount of electronic components are integrated within the first pad 501, and a large amount of electronic components are integrated within the second pad 502, then the first pad 501 and the second pad 502 need to transmit data through the tin paste 508 when the display panel performs video/image displaying, so that all the electronic components within the drive circuit board 50 may act as a whole circuit to enable the drive circuit board 50 to achieve more complete and more complicated circuit functions. On the contrary, if there is communication interruption between the first pad 501 and the second pad 502 within the drive circuit board 50, the display panel will have no access to the normal working state. Therefore, the status display of the display panel may display the communication interconnection information between the first pad 501 and the second pad 502 in real time, and the technician may acquire whether there is successful communication interconnection between the first pad 501 and the second pad 502 through the status display of the display panel, thus improving the communication stability between different electronic components within the drive circuit board 50, and avoiding the problem that communication failure occurs easily between the first pad 501 and the second pad 502 within the drive circuit board 50. In addition, different electronic components within the drive circuit board 50 may always be communicably interconnected to completely implement the corresponding circuit functions, thereby ensuring normal display of image/video information in the display panel, and greatly improving the practical value and human-computer interaction performance of the drive circuit board 50 in the embodiment through the status display of the display panel.

As an alternative implementation, the status display of the display panel may be implemented by using a fault alarm in an exemplary technology, wherein the fault alarm includes electronic components such as a resistor, a MOS tube and a LED and the like, wherein the fault alarm may send a light indication information to the technician through the illumination condition of the LED, and the technician may acquire the communication interconnection state of the first pad 501 and the second pad 502 according to the light indication information. For example, if The first pad 501 and the second pad 502 successfully implement communication interconnection, then the LED in the fault alarm immediately emits light, and the technician may intuitively derive from the optical signal that the communication interconnection is successfully achieved between different pads; if the first pad 501 and the second pad 502 do not implement communication interconnection, then the LED in the fault alarm does not emit light. Therefore, the communication interconnection state of the first pad 501 and the second pad 502 may be displayed intuitively and accurately by the fault alarm in the embodiment, which is simple and convenient to operate and has less error, thereby ensuring that the display panel in the embodiment may be always at normal working state, reducing the communication failure rate between the first pad 501 and second pad 502 within the display panel, and further improving the usage experience of the technician.

FIG. 6 shows a structure of the circuits of the display device 60 provided by an embodiment of the present application. As shown in FIG. 6, the display device 60 includes a signal collector 601, a drive circuit board 602, and a display panel 603, wherein image information may be collected through the signal collector 601, and the display drive signal is generated according to the image information. The display drive signal includes image data, then the signal collector 601 may encode the external image information and convert it into the display drive signal, so that the display drive signal may be quickly transmitted in the internal circuit within the display device 60, and the display device 60 may display the corresponding image or video according to the display drive signal. Therefore, in the embodiment of the present application, the display device 60 may implement communication interconnection with the external electronic devices through the signal collector 601 so as to obtain the external image information.

As an alternative implementation, the above signal collector 601 includes a signal acquisition circuit in an exemplary technology, and the signal acquisition circuit includes electronic components such as an operational amplifier, a transformer and a resistor and the like, then the signal acquisition circuit may collect external physical pulses such as an electrical signal. The image information contained in the electrical signal may be read through the electronic components such as the operational amplifier and the transformer and the like, and may be converted into the display drive signal recognizable by the display device 60, therefore, the embodiment of the present application may acquire image data in real time through the signal collector 601 so as to drive the display device 60 to implement the image display function.

Herein, the drive circuit board 602 is connected to the signal collector 601, and the signal collector 601 transmits the display drive signal to the drive circuit board 602. Through the drive circuit board 602, the display drive signal may be transmitted, so that the display device 60 may receive the display drive signal normally. It should be noted that, the drive circuit board 602 as shown in FIG. 6 is the drive circuit board 50 as shown in FIG. 5, therefore, the working principle and the internal structure of the circuits of the drive circuit board 602 in the embodiment of the present application may refer to the above embodiment as shown in FIG. 5, the details of which will not be repeated here.

The display panel 603 is connected to the drive circuit board 602, and the drive circuit board 602 transmits the display drive signal to the display panel 603, and then the display panel 603 display videos according to the display drive signal. When the display panel 603 receives the display drive signal, the image data is acquired after the display panel 603 decodes the display drive signal, and the display panel 603 is further driven to display the corresponding image or video through the display drive signal, so as to meet viewing requirements of the user.

As an alternative implementation, the display device 60 is a LED (Light Emitting Diode), a LCD (Liquid Crystal Display), an OLED (Organic Light-Emitting Diode), or an electronic display, thus the display circuit board 602 in the embodiment of the present application may be applied to different types of display, and has extremely strong compatibility, which reduces the manufacturing cost and industrial application cost of various types of displays, and provides good usage experience for users.

In the embodiments of the present application, the display device 60 may receive the image information in real time through the signal collector 601, and quickly convert the image information into the display drive signal, and the image data may be transmitted to the display device 60 in real time through the display drive signal, so as to update the image data in the display device 60 in real time. With reference to the above embodiment as shown in FIG. 5, the drive circuit board 602 may quickly transmit and convert the display drive signal, so that the display drive signal has a complete display drive function, then the display panel 603 may receive the display drive signal in real time, and the display drive signal may drive the display panel to display video, so as to meet the visual needs of the user. Thus, the display device 60 in the embodiment of the present application has circuits with simplified structure, the various circuits within the display device 60 are inexpensive and easy to manufacture, which greatly reduces the industrial manufacturing cost and the application cost of the display device 60, and has wide application range. In addition, the user can watch the HD images or videos in real time through the display device 60, which brings a good visual experience for the user. Therefore, the present application effectively solves the problems that the manufacturing cost of the display in the exemplary technology is too high, the internal circuit structure of the display is complicated and the user's usage experience is not good, thus causing the display difficult to be universally suitable for different industrial fields.

FIG. 7 shows a structure of circuits of a display system 70 provided by an embodiment of the present application. As shown in FIG. 7, the display system 70 includes the display device 60 as described above. With reference to the above embodiment as shown in FIG. 6, the display system 70 may display high-definition videos or images, and the industrial application cost of the display system 70 is low, and the application range of the display system 70 is extremely wide as well, which may be universally applied to various industrial fields, gives the user a good usage experience and has strong practicality, thereby effectively solving the problem that the industrial application cost of the display system in the exemplary technology is too high and the user's usage experience is not good.

In summary, the method for manufacturing the printed circuit board 10 in the embodiments of the present application may achieve electrical connection between different pads by using tin paste, and no additional 0Ω resistor is needed, i.e., the cost of the manufacturing material of the printed circuit board 10 is saved, and the manufacturing process of the printed circuit board 10 is simplified as well. Additionally, the printed circuit board 10 in the embodiments of the present application has an extremely simplified circuit structure, and may implement relatively complicated circuit functions, and has strong practicability, which may be widely applied in various industrial fields, and has a strong practical application prospect.

It should be noted that, in this paper, the words such as “a plurality of” or “multiple” refers to a quantity greater than 1, and the relational terms such as “first” and “second” are merely used to distinguish one entity from another, it does not necessarily require or imply any such actual relationship or order between these entities. Moreover, the terms “comprise”, “include” or any other variant is intended to cover non-exclusive inclusions, thus making the terms include the elements inherent in a product or a structure that includes a series of elements. In a condition without more restrictions, the element limited by the phrase “comprise . . . ” or “include . . . ” does not exclude the existence of additional elements in a process, a method, an article or a terminal equipment that include the elements. In addition, in this paper, “greater than”, “less than”, and “more than” etc. are understood as excluding the fundamental number; and “above”, “below”, “less than” are understood as including the fundamental number.

The above description is only the alternative embodiments of the present application, and is not intended to limit the present application. Any modification, equivalent substitution and improvement made within the spirit and principles of the present application should be included in the scope of the present application.

1. A method for manufacturing a printed circuit board, the printed circuit board comprises a plurality of electrically isolated pads each comprising a pad body and a protrusion extending from a side of the pad body, wherein the protrusions of adjacent two of the pads are arranged oppositely, the method comprises:
arranging an electrical isolation region between the protrusions of the adjacent two of the pads;
overlapping a steel screen on the surface of the printed circuit board, wherein the steel screen is provided with meshes, and the meshes correspond to at least part of two of the pads and the electrical isolation region between the two of the pads, respectively; and
printing tin onto the surface of the steel screen, such that the electrical isolation region between adjacent two of the pads is covered with tin paste.

2. The method of claim 1, wherein the meshes correspond to two of the pads and the electrical isolation region between the two of the pads, respectively.

3. The method of claim 2, wherein, printing tin onto the surface of the steel screen, such that two of the pads and the electrical isolation region between the adjacent two of the pads are covered with the tin paste.

4. The method of claim 1, wherein the meshes completely overlap the electrical isolation region between the two of the pads, respectively.

5. The method of claim 1, wherein the pad body is of a rectangular shape or an elliptical shape.

6. The method of claim 1, wherein the method further comprises, after printing tin onto the surface of the steel screen such that the electrical isolation region between adjacent two of the pads is covered with the tin paste,
performing serial communication detection for adjacent two of the pads to determine whether or not adjacent two of the pads can implement communication interconnection.

7. The method of claim 6, wherein the method further comprises:
sending communication interconnection indication signal when adjacent two of the pads can implement communication interconnection.

8. The method of claim 1, wherein, that printing tin onto the surface of the steel screen such that the electrical isolation region between adjacent two of the pads is covered with the tin paste is specifically as follows:
printing tin onto the surface of the steel screen, wherein the tin paste flows through the meshes of the steel screen and onto the electrical isolation region between adjacent two of the pads, such that the electrical isolation region between adjacent two of the pads is covered with the tin paste, and the tin paste fails to flow through the region of the steel screen without meshes.

9. A printed circuit board, comprising a plurality of electrically isolated pads, wherein each of the pads comprises a pad body and a protrusion extending from a side of the pad body, wherein the protrusions of adjacent two of the pads are arranged oppositely, and the region between the protrusions of adjacent two of the pads is covered with tin paste.

10. The printed circuit board of claim 9, wherein, in the pads, the pad body is of a rectangular shape or an elliptical shape.

11. The printed circuit board of claim 9, wherein the printed circuit board further comprises:
a communication detector in connection with the pads, the communication detector is configured to detect whether or not adjacent two of the pads can implement communication interconnection.

12. The printed circuit board of claim 11, wherein the printed circuit board further comprises:
a status display in connection with the communication detector, wherein the status display is configured to display communication interconnection information of the adjacent two of the pads.

13. The printed circuit board of claim 9, wherein the adjacent two of the pads and the region between the protrusions of the adjacent two of the pads are both covered with tin paste.

14. A drive circuit board, comprising a first pad and a second pad, wherein the first pad comprises a first pad body and a first protrusion extending from a side of the first pad body, the second pad comprises a second pad body and a second protrusion extending from a side of the second pad body,
wherein the first protrusion and the second protrusion are arranged oppositely, and the region between the first protrusion and the second protrusion is covered with tin paste.

15. The drive circuit board of claim 14, wherein the first pad body is of a rectangular shape or an elliptical shape, and the second pad body is of a rectangular shape or an elliptical shape.

16. The drive circuit board of claim 14, wherein the first pad and the second pad are in communication connection through tin paste.

17. The drive circuit board of claim 14, wherein the first pad, the second pad and the region between the first protrusion and the second protrusion are covered with tin paste.

18. The drive circuit board of claim 14, wherein the first pad comprises:
a power circuit, configured to output DC power; and
a control circuit, which is connected to the power circuit and configured to access a display drive signal and generate a display control signal;
the second pad comprises:
a gate drive circuit, configured to receive the display drive signal according to the display control signal; and
a source drive circuit, configured to convert and the display drive signal according to the display control signal and output the converted display drive signal.

19. The drive circuit board of claim 18, wherein the power circuit comprises a power management chip, and the control circuit comprises a display drive chip.

20. The drive circuit board of claim 18, wherein the drive circuit board further comprises:
a display-panel-status display, the display-panel-status display is connected with the first pad and the second pad, and the display-panel-status display is configured to display communication interconnection information of the first pad and the second pad.
